(19) United States
(12) Patent Application Publication
(10) Pub. No.: US 2010/0091630 A1
(43) Pub. Date: Apr. 15, 2010

(54) METHOD FOR MANUFACTURING SEMICONDUCTOR DEVICE, OPTICAL PICKUP MODULE AND SEMICONDUCTOR DEVICE

(76) Inventors: Junya Furuyashiki, Kagoshima (JP); Syouzou Moribe, Kagoshima (JP); Hiroki Utatsu, Kagoshima (JP); Noriyuki Yoshikawa, Osaka (JP); Toshiyuki Fukuda, Kyoto (JP); Masanori Minamio, Osaka (JP); Hiroyuki Ishida, Osaka (JP)

Correspondence Address: MCDERMOTT WILL & EMERY LLP, 600 13TH STREET, NW, WASHINGTON, DC, 20005-3096, US

(21) Appl. No.: 12/525,227

(22) PCT Filed: Mar. 10, 2008
(86) PCT No.: PCT/JP2008/000515

§ 371 Date: Jul. 30, 2009

(30) Foreign Application Priority Data
Mar. 14, 2007 (JP) 2007-064827

(51) Int. Cl. G11B 7/00; H01L 21/78; H01L 23/29

(52) U.S. Cl. 369/100; 438/113; 257/729; G9B/7; 257/E23.119; 257/E21.599

(57) ABSTRACT

A plurality of parallel rib prototypes are provided on a flat base plate. A plurality of semiconductor elements are placed in each trench between adjacent ones of the rib prototypes, and a transparent member is bonded to each of the semiconductor elements. Electrode pads of the semiconductor elements are wire bonded to connection electrodes. The trenches are then filled with an encapsulating resin. Thereafter, middle portions, in the longitudinal direction, of the rib prototypes are cut with a dicing saw, and adjacent ones of the semiconductor elements are separated from each other, thereby obtaining semiconductor devices.

### TECHNICAL FIELD

The present invention relates to methods for fabricating semiconductor devices, optical pickup modules, and semiconductor devices.

### BACKGROUND ART

Conventional optical disk drives for reading signals from optical disks such as DVDs are provided with optical pickup modules in each of which a semiconductor laser for emitting light for reading, and a photodetector for receiving feedback light reflected from optical disks are mounted on the same base.

As disclosed in Patent Document 1, an optical disk drive includes an optical pickup module located under the optical recording surface of an optical disk and configured to move along the radius of the optical disk. Because of this configuration, size reduction of the optical disk drive requires miniaturization of the optical pickup module, which further requires miniaturization of the photodetector.

For example, Patent Document 2 discloses a method for fabricating a solid-state imaging device. This method is intended for miniaturization of a photodetector by reducing the size of a housing for accommodating a solid-state imaging element. Specifically, the method includes: resin-molding a housing including a base and rectangular frame-shaped ribs in one piece with a plurality of metal lead pieces, forming internal terminal portions and external terminal portions with the metal lead pieces; fixing an imaging element onto the base inside an internal space of the housing; connecting electrodes of the imaging element respectively to the inner terminal portions of the metal lead pieces; and fixing a transparent plate to an upper face of the ribs. In this method, in order to locate the transparent plate, a stepped portion is formed on the top face of the ribs, providing a lower step that is lowered along an internal periphery, the transparent plate has a size capable of being mounted onto an upper surface of the lower step within a region inward of an inner wall formed by the stepped portion of the ribs, and when fixing the transparent plate to the upper face of the ribs, an adhesive is provided on the upper face of the lower step, then the transparent plate is placed on the adhesive to be fixed to the upper surface of the lower step while regulating its position with the inner wall of the stepped portion, and then the portion positioned outside the stepped portion of the ribs is removed.
Patent Document 1: Japanese Laid-Open Patent Publication No. 2001-56950
Patent Document 2: Japanese Laid-Open Patent Publication No. 2005-64292
Patent Document 3: Japanese Laid-Open Patent Publication No. 2005-79537
Patent Document 4: Japanese Laid-Open Patent Publication No. 2002-164524

### DISCLOSURE OF INVENTION

### Problems that the Invention is to Solve

However, as illustrated in FIG. 18, in the solid-state imaging device disclosed in Patent Document 2, rectangular frame-shaped ribs 203 are provided on the external edges of a base 202 onto which an imaging element 205 is mounted. The four sides of the rectangular ribs 203 have an identical width, and thus miniaturization has limitations. The solid-state imaging device disclosed in Patent Document 3 has similar drawbacks. In a conventional fabrication method, a lead frame is placed as a base to be resin molded in one piece, thereby forming an original plate in which a plurality of housings are connected to each other, and then an imaging element is mounted. In this method, an expensive molding die is necessary, and ribs need to be formed in one piece with a lead frame by resin molding. In addition, in resin molding the ribs with the die, a small draft of 5 to 15° need to be provided on side surfaces of the ribs in order to take the product out of the die after the resin molding, and thus it was impossible to form vertical ribs. Further, the conventional method has a problem in which the design of the shape of the ribs cannot be easily changed because of the use of a die for resin molding.

It is therefore an object of the present invention to provide a method for efficiently fabricating a semiconductor device which can be reduced in overall size, particularly in the length of a pair of two opposite sides out of the four sides of a substantially rectangular package.

### Means of Solving the Problems

To achieve the object, a first fabrication method according to the present invention is a method for fabricating a semiconductor device including a semiconductor element and a package on which the semiconductor element is mounted. The method includes: providing, on an upper surface of a flat base plate, a plurality of parallel ribs projecting from the upper surface of the base plate, thereby forming a package-assembled board in which a plurality of packages are connected to one another; placing a plurality of semiconductor elements between adjacent two of the ribs along a direction in which the ribs extend; and cutting the package-assembled board at a middle portion of each of the ribs along the direction in which the ribs extend.

In a preferred embodiment, a slit is formed in each of the ribs from an upper surface of the rib toward the base plate, and extends along a direction in which the rib extends.

A second fabrication method according to the present invention is a method for fabricating a semiconductor device including a semiconductor element and a package on which the semiconductor element is mounted. The method includes: providing, on an upper surface of a flat base plate, a plurality of parallel ribs projecting from the upper surface of the base plate in such a manner that the ribs are spaced apart at two distances which are alternately a first distance a and a second distance b smaller than the first distance a, thereby forming a package-assembled board in which a plurality of packages are connected to one another; placing, along a direction in which the ribs extend, a plurality of semiconductor elements between adjacent two of the ribs spaced apart at the first distance a; and cutting, along the direction in which the ribs extend, the package-assembled board at a portion between adjacent two of the ribs spaced apart at the second distance b.

Each of the ribs may have a plurality of recessed portions, one of whose width and height is smaller than the other portion and which are arranged along the direction in which the rib extends, and in the placing, each of the semiconductor elements may be placed between adjacent two of the ribs and, in the direction in which the ribs extend, between adjacent two of the recessed portions.

The package-assembled board may include a plurality of connection electrodes arranged on the upper surface of the base plate along the ribs, and in the placing, the semiconductor elements and the connection electrodes may be connected to each other by metal wires.

The method may further include: placing a transparent member having a plate shape on each of the semiconductor elements; and encapsulating the metal wires and a side wall surface of the transparent member with an encapsulating resin.

In the placing the transparent member, the transparent member may be commonly placed on the plurality of semiconductor elements.

An optical pickup module according to the present invention includes: a semiconductor device fabricated with one of the methods described above; a laser module; and a beam splitter, wherein a semiconductor element included in the semiconductor device is a photoreceiver.

The optical pickup module may further include a mirror and an objective lens.

The optical pickup module may be placed under an information-recording surface of an optical disk, and a direction along which the ribs extend may be substantially perpendicular to the information-recording surface.

The laser module may include: a blue-violet laser device configured to emit light having a peak wavelength ranging from 385 nm to 425 nm, both inclusive; and a dual-wavelength laser device configured to emit light having a peak wavelength ranging from 630 nm to 670 nm, both inclusive, and light having a peak wavelength ranging from 760 nm to 800 nm, both inclusive.

A semiconductor device according to the present invention includes: a semiconductor element; and a package on which the semiconductor element is mounted, wherein the semiconductor device is a substantially rectangular solid, a bottom surface and a pair of opposite side surfaces of the semiconductor device are part of the package, the package includes a base which is substantially rectangular and has a mounting surface on which the semiconductor element is mounted, and ribs respectively provided on a pair of opposite external edges of the mounting surface and extending along the pair of opposite external edges, the semiconductor element is encapsulated with an encapsulating resin, a pair of opposing surfaces of the respective ribs are covered with the encapsulating resin, the board, the ribs, and the encapsulating resin are exposed at another pair of opposite side surfaces of the semiconductor device, and a portion of each of the ribs covered with the encapsulating resin has a wide portion located at a lower surface of the rib and having a width, in a direction perpendicular to a direction in which the rib extends, larger than that of a portion of the rib exposed at one of the another pair of opposite side surfaces of the semiconductor device. The lower surface of the rib herein is a portion (i.e., surface) of the rib in contact with the mounting surface.

The lower surface of each of the ribs and the mounting surface may be bonded together with an adhesive, and the adhesive may form a fillet at a portion where a side wall surface of the wide portion and the mounting surface are bonded together. The fillet herein refers to a narrow strip adhering to both the side wall surface of the wide portion and the mounting surface.

A side surface of each of the ribs opposite one of opposing surfaces of the respective ribs may exhibit a surface roughness smaller than that of a surface of the encapsulating resin exposed at one of the another pair of opposite side surfaces of the semiconductor device.

Side surfaces of the ribs may be substantially perpendicular to the mounting surface.

### Effects of the Invention

With a method for fabricating a semiconductor device according to the present invention, a package-assembled board is obtained with a plurality of parallel ribs formed on the upper surface of a flat base plate, and semiconductor elements are placed between these ribs. Accordingly, the length of the semiconductor device along the direction in which the ribs extend can be made substantially as small as the size of the semiconductor elements, thus efficiently fabricating small-size semiconductor devices.

### BRIEF DESCRIPTION OF DRAWINGS

FIG. 1(a) is a perspective view illustrating a semiconductor device according to a first embodiment. FIG. 1(b) is a view of the bottom in FIG. 1(a).

FIG. 2(a) is a top view illustrating the semiconductor device of the first embodiment with an encapsulating resin removed. FIG. 2(b) is a cross-sectional view taken along line A-A′ in FIG. 2(a). FIG. 2(c) is a cross-sectional view taken along line B-B′ in FIG. 2(a).

FIG. 3 shows fabrication of the semiconductor device of the first embodiment in chronological order.

FIG. 4 is a perspective view illustrating an example of a package-assembled board.

FIG. 5 is a perspective view illustrating another example of the package-assembled board.

FIG. 6 is a perspective view illustrating a package-assembled board according to a second embodiment.

FIG. 7(a) is a cross-sectional view illustrating a semiconductor device according to a third embodiment. FIG. 7(b) is a cross-sectional view illustrating another semiconductor device according to a fourth embodiment.

FIG. 8(a) is a perspective view illustrating the semiconductor device of the fourth embodiment. FIG. 8(b) is a view of the bottom in FIG. 8(a).

FIG. 9(a) is a top view illustrating the semiconductor device of the fourth embodiment with an encapsulating resin removed. FIG. 9(b) is a cross-sectional view taken along line A-A′ in FIG. 9(a). FIG. 9(c) is a cross-sectional view taken along line B-B′ in FIG. 9(a).

FIG. 10(a) is a top view illustrating a semiconductor device according to a fifth embodiment. FIG. 10(b) is a cross-sectional view taken along line A-A′ in FIG. 10(a). FIG. 10(c) is a cross-sectional view taken along line B-B′ in FIG. 10(a).

FIG. 11 is a perspective view illustrating a package-assembled board according to a sixth embodiment.

FIG. 12(a) is a perspective view illustrating a semiconductor device according to a seventh embodiment. FIG. 12(b) is a perspective view illustrating a rib.

FIG. 13(a) is a perspective view illustrating a semiconductor device according to an eighth embodiment. FIG. 13(b) is a perspective view illustrating a rib.

FIG. 14 is a perspective view illustrating a rib according to a ninth embodiment.

FIG. 15 is a perspective view illustrating a rib according to a modified example of the ninth embodiment.

FIG. 16 is a perspective view schematically illustrating an optical pickup module according to the first embodiment.

FIG. 17 is a front view schematically illustrating an optical pickup module according to the first embodiment.

FIG. 18 is a top view illustrating a conventional semiconductor device including a photoreceiver.

### DESCRIPTION OF SYMBOLS

1, 2, 3, 4, 5 semiconductor device
6, 7 semiconductor device
10 semiconductor element
22 metal wire
30 plate-like side wall
41 first laser device
42 second laser device
43 beam splitter
45 mirror
46 objective lens
47 optical disk
49 laser module
50, 51, 52 package
60 base
61 base plate
62 mounting surface
64 non-mounting surface
68 fillet
70 rib
70a rib external side wall surface
70b rib upper surface
71, 72, 73, 74 rib
71a, 72a rib external side wall surface
71c, 72c wide portion
73c, 74c wide portion
75 connection electrode
76 internal interconnection
77 external-connection portion
80, 84, 85, 86 rib prototype
94, 94a, 94′ transparent member
96 encapsulating resin
100, 101, 102 package-assembled board

### BEST MODE FOR CARRYING OUT THE INVENTION

Hereinafter, embodiments of the present invention will be specifically described with reference to the drawings. In the drawings, components having substantially the same functions are denoted by the same reference character for simplicity of the description.

### Embodiment 1

### —Semiconductor Device—

A semiconductor device fabricated with a fabrication method according to the first embodiment is a photodetector employing an integrated photoreceiver as a semiconductor element. The semiconductor element may be a photoreceiver such as a photodiode, a phototransistor, and a photo IC, or a light-emitting element such as an LED and a semiconductor laser.

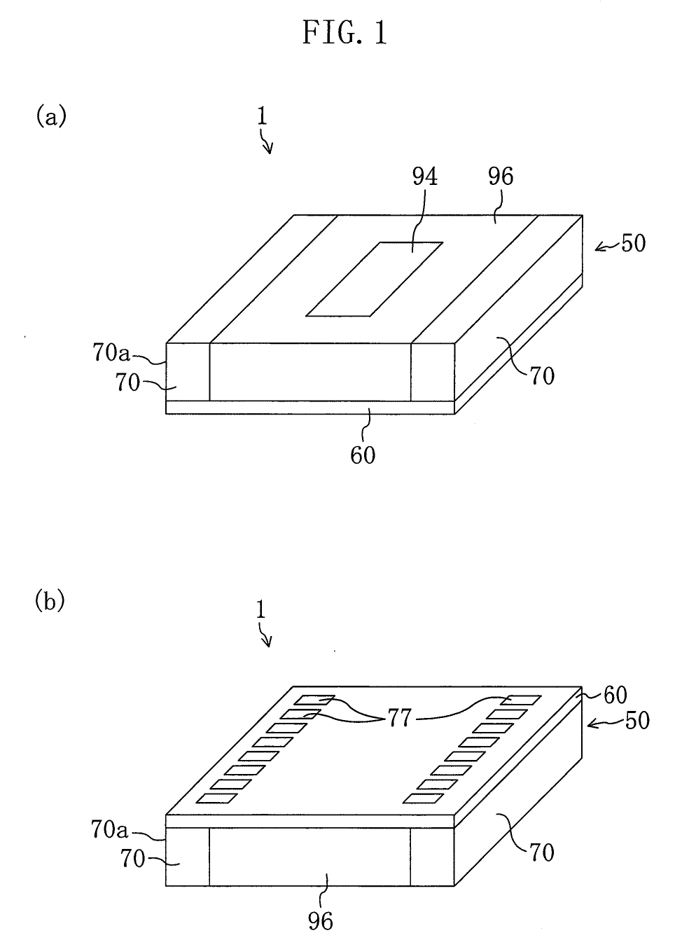

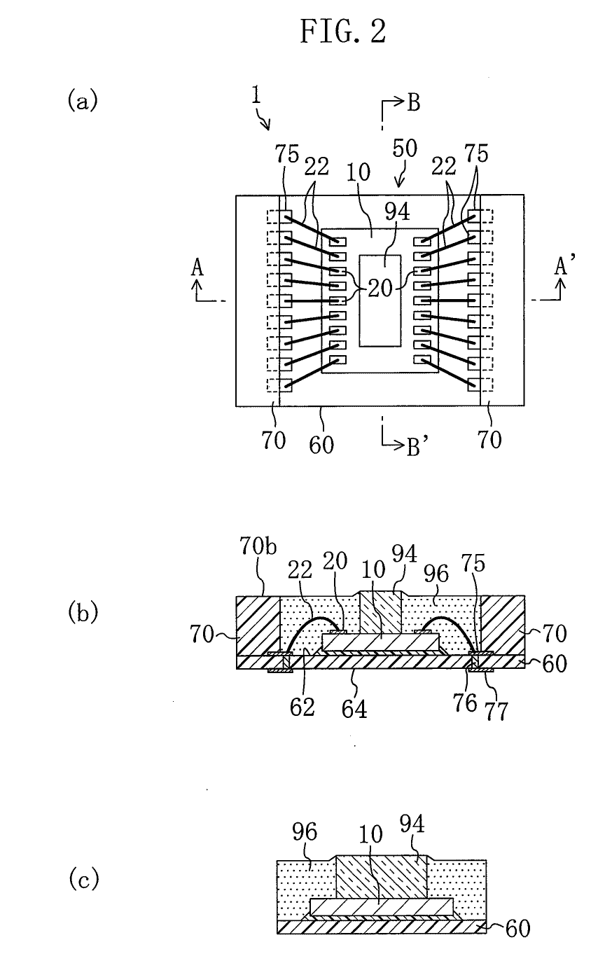

As illustrated in FIGS. 1 and 2, in a semiconductor device 1 of this embodiment, a semiconductor element 10 is housed in a recess of a recessed package 50 having a “U” shape in cross section, and a plate-like transparent member 94 is placed on the semiconductor element 10 to cover the light-receiving surface of the semiconductor element 10 with a transparent adhesive interposed between the transparent member 94 and the semiconductor element 10. The package 50 is filled with an encapsulating resin 96. The transparent member 94 is a plate-like member having a rectangular upper surface and made of glass, and adheres to the semiconductor element 10. For convenience of description, the encapsulating resin 96 is not shown in FIG. 2(a).

The package 50 of this embodiment includes: a rectangular base 60; and two ribs 70, 70 projecting upward from the base 60 and respectively extending along a pair of opposite sides of the rectangle. The ribs 70, 70 are respectively provided only on a pair of opposite external edges of a rectangular mounting surface 62 of the base 60 on which the semiconductor element 10 is mounted. Each of the ribs 70, 70 is in the shape of a rectangular solid extending along an associated one of the external edges of the mounting surface 62. The phrase “the ribs 70, 70 are provided only on a pair of external edges of the mounting surface 62” means that the ribs 70, 70 are respectively provided on the above-mentioned pair of external edges but no ribs 70, 70 are provided on another pair of opposite external edges of the mounting surface 62 and a center portion and its periphery of the mounting surface 62.

On the mounting surface 62, a plurality of connection electrodes 75, 75, . . . are aligned between the mounted semiconductor element 10 and each of the ribs 70. Each of the connection electrodes 75 extends to a portion under an associated one of the ribs 70, and is partially hidden under the rib 70. The connection electrodes 75 are connected to buried electrodes 76, 76, . . . provided in the base 60. A plurality of external-connection portions 77, 77, . . . are provided on a non-mounting surface 64 of the base 60 opposite the mounting surface 62, and are connected to the buried electrodes 76, 76, . . . . That is, the connection electrodes 75, 75, . . . are electrically connected to the external-connection portions 77, 77, . . . via the buried electrodes 76, 76, . . . .

The semiconductor element 10 is rectangular, and a plurality of electrode pads 20, 20, . . . are aligned along each of a pair of two opposite sides of a surface of the semiconductor element 10. The surface of the semiconductor element 10 opposite the surface on which the electrode pads 20, 20, . . . are provided is mounted on the mounting surface 62, and is fixed to the mounting surface 62 with an adhesive. At this time, the semiconductor element 10 is mounted on the package 50 in such a manner that the electrode pads 20, 20, . . . are arranged in lines substantially in parallel with the direction along which the ribs 70, 70 extend. The electrode pads 20, 20, . . . are connected to the connection electrodes 75, 75, . . . by metal wires 22, 22, . . . .

The trench of the package is filled with an encapsulating resin 96 in such a manner that the side surface of the transparent member 94 and the metal wires 22, 22, . . . are buried in the encapsulating resin 96. In this manner, components in a trench (a recess) of the package 50 except for the upper surface of the transparent member 94 and rib upper surfaces 70b are encapsulated with the encapsulating resin 96. Specifically, the side surface of the transparent member 94, the upper surfaces of the ribs 70, 70, and the metal wires 22, for example, are buried in the encapsulating resin 96.

When viewed from above the semiconductor device 1 of this embodiment, only the upper surface of the transparent member 94 and the rib upper surfaces 70b are exposed, and the other components are covered with the encapsulating resin 96. Accordingly, no dirt and dust accumulate on the light-receiving surface of the semiconductor element 10, electrode pads 20, the connection electrodes 75, and the metal wires 22, thus avoiding failures such as occurrence of portions incapable of receiving light and short circuits caused by dirt and dust. The encapsulating resin 96 is preferably one of a thermosetting epoxy resin, a filler-added resin containing, for example, SiO₂, and a resin which contains a dye and exhibits a light-blocking property, for example.

In addition, a rib external side wall surface 70a and a side wall surface of the base 60 are flush with each other at each side wall surface of the semiconductor device 1. This structure can reduce the length of the side of the semiconductor device 1 between the ribs 70, 70, thus contributing to miniaturization. The “external side wall surfaces” herein refer to the side wall surfaces of the ribs 70, 70 opposite the side wall surfaces thereof facing the semiconductor element 10.

The rib external side wall surfaces 70a and the side wall surfaces opposite the surfaces 70a are perpendicular to the mounting surface 62. With this structure, the width of the ribs 70 and the distance between the two ribs 70, 70 can be more arbitrarily selected than in the case of forming ribs 70 by resin molding with a die. The surface roughness of the rib external side wall surfaces 70a is greater than that of portions of the encapsulating resin 96 exposed at the side wall surfaces. This is because the rib external side wall surfaces 70a are used for positioning in placing the semiconductor device in an optical pickup module.

The encapsulating resin 96 is a high-viscosity liquid when filling the trench of the package 50, and is then cured. At the side wall surfaces of the semiconductor device 1 except for the rib external side wall surfaces 70a, the encapsulating resin 96 is flush with the end surfaces of the ribs 70, 70. The metal wires 22 are completely buried in the encapsulating resin 96, and thus portions of the metal wires 22 in contact with the electrode pads 20 and with the connection electrodes 75 are fixed, thus enhancing connection reliability. In addition, since the upper surface of the transparent member 94 is exposed and the side surfaces of the transparent member 94 are buried in the encapsulating resin 96, only light that has passed through the upper surface of the transparent member 94 reaches the light-receiving surface of the semiconductor element 10. Even when light enters the side surfaces of the transparent member 94, such unnecessary light does not reach the light-receiving surface. Consequently, stray light (i.e., diffuse reflection of light) can be eliminated, and thus optical properties can be enhanced.

In this embodiment, no ribs are provided on a pair of opposite external edges of the base 60 different from the pair of opposite external edges of the base 60 on which the ribs 70, 70 are provided. Thus, the distance between the pair of opposite external edges on which no ribs are provided is determined according to the size of the semiconductor element 10 and the area necessary for arranging the connection electrodes 75, 75, . . . . That is, the distance between the pair of opposite external edges with no ribs can be minimized in a package on which the semiconductor element 10 is mounted.

With respect to the height (i.e., distance) from the mounting surface 62 of the base 60, the height of the upper surface of the transparent member 94 is larger than those of the rib upper surfaces 70b and the upper surface of the encapsulating resin 96. Accordingly, in placing the semiconductor device 1 in an optical pickup module, the upper surface of the transparent member 94 that is parallel to the light-receiving surface of the semiconductor element 10 and has a large area can be easily used as a reference surface for the placement. In addition, accuracy in the placement in the optical pickup module can be easily enhanced. Further, the placement can be easily performed for a short period of time.

### —Method for Fabricating Semiconductor Device—

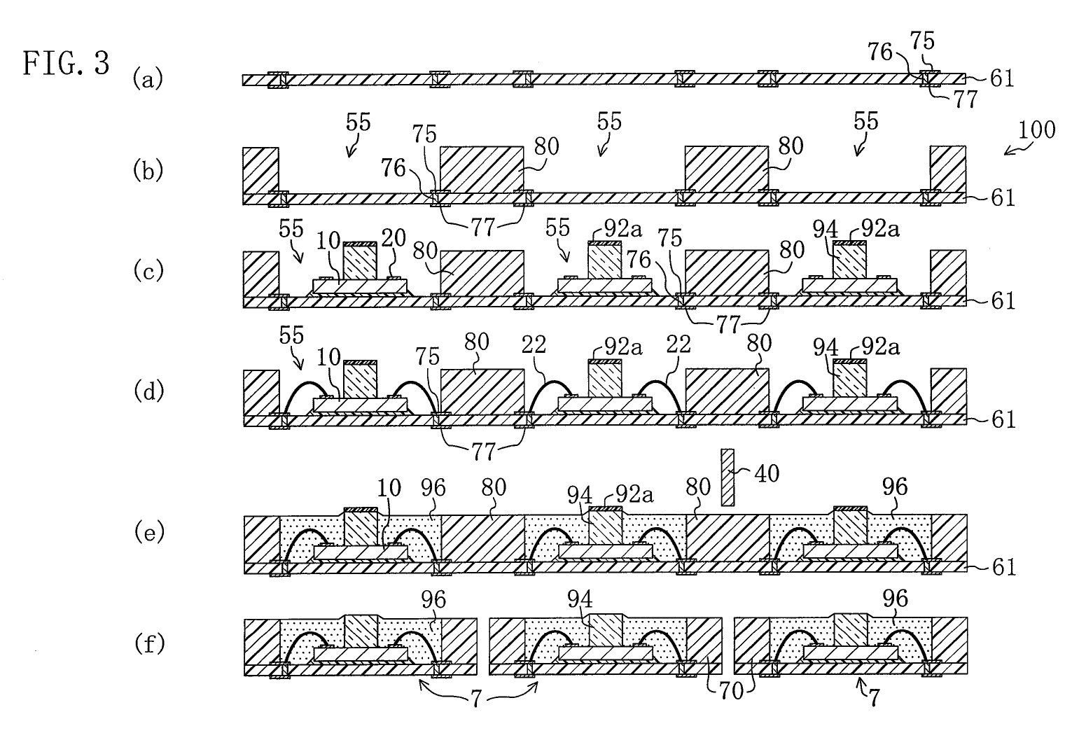

A method for fabricating a semiconductor device 1 according to this embodiment is now described with reference to FIG. 3.

First, as illustrated in FIG. 3(a), a base plate 61 is prepared. This base plate 61 can be fabricated with a known method. For example, a line of a plurality of through holes is formed in an insulating board in the shape of a flat plate. A plurality of such lines of through holes are provided in parallel to each other. Then, a conductor is buried in these through holes to form buried electrodes 76, 76, . . . . Thereafter, connection electrodes 75, 75, . . . connected to the buried electrodes 76, 76, . . . are formed on the upper surface of the insulating board, whereas external-connection portions 77, 77, . . . are formed on the lower surface of the board. In this manner, a base plate 61 is obtained.

Next, as shown in FIG. 3(b), rib prototypes 80, 80, . . . in the shape of quadrangular prisms are provided on the connection electrodes 75, 75, . . . and fixed thereto with an adhesive in such a manner that each of the rib prototypes 80 is located on a pair of adjacent two lines of the connection electrodes 75, 75 with a trench 55 left between the pairs of adjacent two lines of the connection electrodes 75, 75, . . . . In this manner, a package-assembled board 100 is obtained. The rib prototypes 80, 80, . . . are located on respective parts of the connection electrodes 75, 75, . . . . The rib prototypes 80, 80, . . . are included in ribs in claims below.

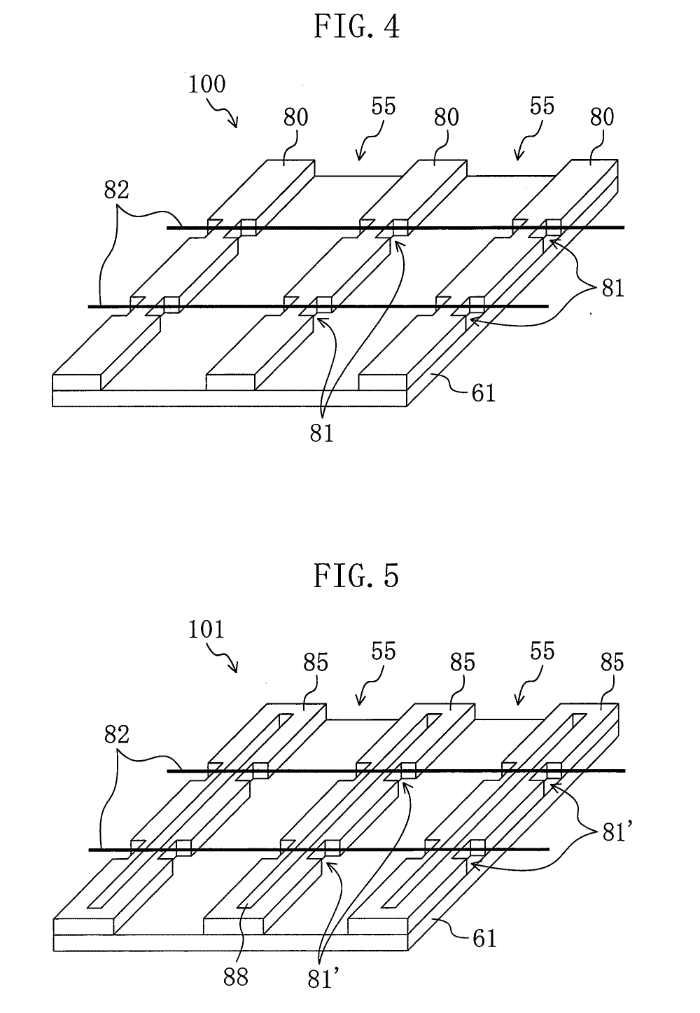

As illustrated in FIG. 4 (where the connection electrodes are not shown), a plurality of recessed portions 81, 81, . . . each having a small width are provided in each of the rib prototypes 80 along the direction in which the rib prototype 80 extends. The recessed portions 81, 81, . . . are aligned in a direction perpendicular to the direction in which the rib prototypes 80 extend. In a subsequent process step, the board is cut at these portions. Reference character 82 denotes these cutting lines.

In the package-assembled board 100, a plurality of packages 50 described above are arranged, and rib external side wall surfaces 70a of adjacent ones of the packages 50 are united. Along the direction in which the ribs 70 extend, a plurality of packages 50 are also arranged and united.

Then, a plurality of semiconductor elements 10 are mounted on, and fixed to, each of the bottom surfaces of the trenches 55, 55, 55 along the direction in which the trenches 55, 55, 55 extend. Thereafter, transparent members 94 are placed on the light-receiving surfaces of the semiconductor elements 10, and are fixed to these light-receiving surfaces with a transparent adhesive. At this time, protective sheets 92a are provided on the upper surfaces of the transparent members 94. In this manner, the state illustrated in FIG. 3(c) is obtained. In this configuration, each of the semiconductor elements 10 is placed in an associated one of the trenches 55 between adjacent ones of the cutting lines 82, 82, i.e., between adjacent ones of the recessed portions 81, 81 disposed along the direction in which the rib prototypes 80 extend.

Subsequently, electrode pads 20 of the semiconductor elements 10 are wire bonded to connection electrodes 75. In this manner, as illustrated in FIG. 3(d), the electrode pads 20 and the connection electrodes 75 are connected to each other by metal wires 22.

Thereafter, the trenches 55 are filled with an encapsulating resin 96. This filling may be achieved by potting or injection molding. At this time, the entire upper surfaces of the transparent members 94 are covered with the protective sheets 92a. This structure ensures that the upper surfaces of the transparent members 94 are not covered with the encapsulating resin 96 and are exposed. FIG. 3(e) shows a state in which the encapsulating resin 96 fills the trenches, and is cured. The side wall surfaces of the rib prototypes 80 are encapsulated with the encapsulating resin 96, and the upper surfaces of the rib prototypes 80 are exposed from the encapsulating resin 96.

Subsequently, the board is cut with a dicing saw 40 at middle portions of the rib prototypes 80 along the direction in which the rib prototypes 80 extend. In this manner, side wall surfaces are made flush with one another. Thereafter, the board is cut again along the cutting lines 82, 82 each located between adjacent ones of the semiconductor elements 10, perpendicularly to the direction in which the trenches 55 extend. Then, the protective sheets 92a are removed. The state after the cutting is illustrated in FIG. 3(f). In this manner, individual semiconductor devices 1 are obtained. In cutting the board into the individual semiconductor devices 1, the rib prototypes 80 are cut at the recessed portions 81. Accordingly, cutting resistance can be reduced, thus reducing stress on the packages 50.

The above-described method for fabricating semiconductor devices 1 is merely an example, and the fabrication method of this embodiment is not limited to this example. For example, as illustrated in FIG. 5, a package-assembled board 101 including slits 88 may be used. These slits 88 are formed at respective middle portions of rib prototypes 85 along the rib prototypes 85 and penetrate the rib prototypes 85 from the upper surfaces of the rib prototypes 85 to reach the base plate 61. The use of such a package-assembled board 101 can suppress warping or deforming of the package-assembled board 101 even with an increase (in the area) of the package-assembled board 101, and allows separation with a dicing saw 40 to be easily performed for a short period of time, resulting in easy processing.

The slits 88 do not need to penetrate the rib prototypes 85. Even in this case, the foregoing advantages can be achieved as long as the slits 88 reach about the middle of the thickness of the rib prototypes 85, for example. In addition, slits may also be formed in the base plate 61 at locations corresponding to the slits 88 of the rib prototypes 85. The shape of each of the rib prototypes is not limited to a quadrangular prism having a rectangular cross section, and may be a trapezoidal prism, a semi-cylindrical shape, or a triangular prism. The width of the dicing saw 40 may be larger or smaller than that of the slits 88. When the width of the dicing saw 40 is smaller than that of the slits 88, the surface roughness of the rib external side wall surfaces 70a becomes equal to a previously-set surface roughness of the inner walls of the slits 88. This ensures that the surface roughness of the rib external side wall surfaces 70a is smaller than that of portions of the encapsulating resin 96 exposed at the side wall surfaces.

### —Optical Pickup Module—

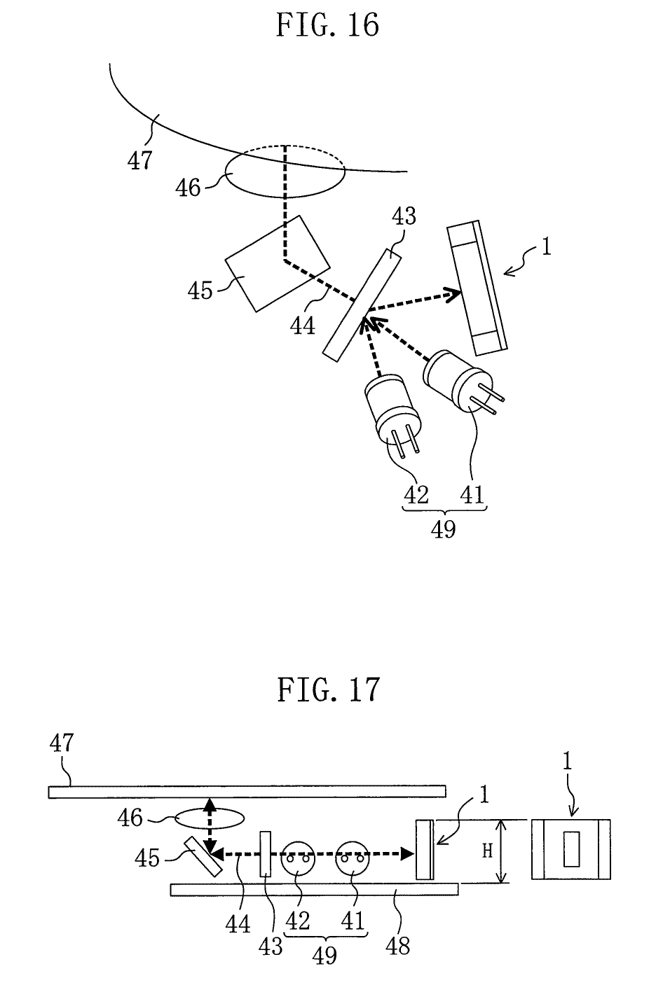

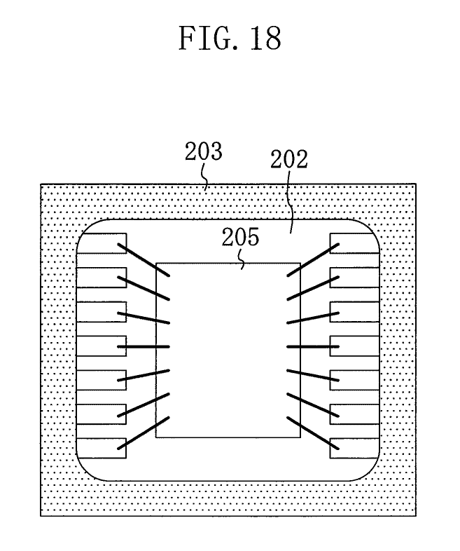

FIG. 16 is a perspective view schematically illustrating a configuration in which an optical pickup module according to this embodiment is placed under an optical disk 47. FIG. 17 is a side view of the configuration. The semiconductor device 1 at the right side of FIG. 17 is shown in order to depict the light-receiving surface of the semiconductor device 1 (photodetector) mounted on a support 48, which is located at the left of the right-side semiconductor device 2, with the semiconductor device 1 rotated 90° with respect to the vertical axis. The illustration does not mean that two semiconductor devices 1 are provided in the optical pickup module.

This optical pickup module includes the above-described semiconductor device 1 (photodetector), first and second laser devices 41 and 42, a beam splitter 43, a mirror 45, and an objective lens 46. The first and second laser devices constitute a laser module 49. Light 44 emitted from the first and second laser devices 41 and 42 passes through the beam splitter 43, is reflected on the mirror 45, and then strikes an information-recording surface of the optical disk 47 through the objective lens 46. The light 44 is then reflected on the information-recording surface, and enters the semiconductor device 1 by way of the objective lens 46, the mirror 45, and the beam splitter 43.

In this case, the first laser device 41 is a blue-violet laser device configured to emit laser light having a peak wavelength of 405 nm. The second laser device 42 is a dual-wavelength laser device configured to emit laser light with two wavelengths: red laser light having a peak wavelength of 650 nm; and infrared laser light having a peak wavelength of 780 nm.

Components constituting the optical pickup module are mounted on the support 48, and this support 48 is placed under the information-recording surface of the optical disk 47. Under the rotating optical disk 47, the optical pickup module moves along the radius of the optical disk 47. The surface of the support 48 on which the components are mounted is in parallel with the information-recording surface of the optical disk 47.

For convenience in establishing interconnection, the semiconductor device 1 is positioned in such a manner that the direction along which the ribs 70, 70 extend is perpendicular to the support 48, i.e., to the information-recording surface of the optical disk 47. With this positioning, a plurality of external-connection portions 77, 77, . . . of the semiconductor device 1 are arranged in two lines perpendicularly to the mounting surface of the support 48. Accordingly, wires drawn from the external-connection portions 77, 77, . . . to establish connection to the outside are arranged within the height H of the semiconductor device 1 from the mounting surface of the support 48, resulting in reduction of the height of the entire optical pickup module.

As described above, the ribs 70, 70 of the semiconductor device 1 extend perpendicularly to the support 48, and no ribs extend in parallel with the support 48. This configuration allows the height H of the semiconductor device 1 to be made approximately equal to the length of one side of the semiconductor element 10. As a result, the entire optical pickup module can be thinner, and smaller in size.

### Embodiment 2

A method for fabricating a semiconductor device according to a second embodiment differs from that of the first embodiment only in rib prototypes. Thus, aspects different from those of the first embodiment are now described.

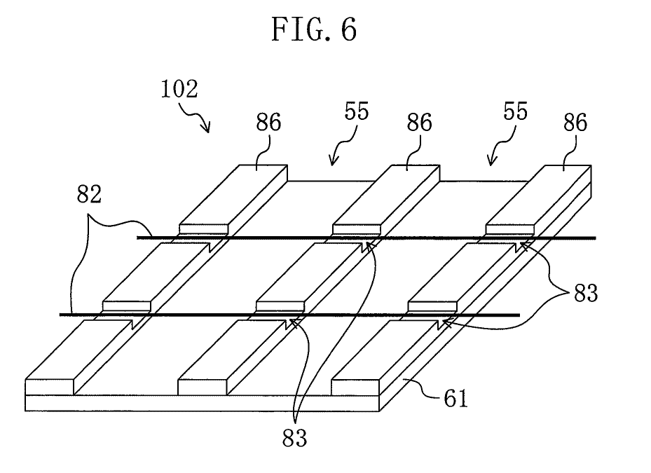

As illustrated in FIG. 6, rib prototypes 86 of this embodiment have recessed portions 83 whose thickness is smaller than the other portion of the rib prototypes 86. This structure can reduce the resistance in cutting the rib prototypes 86 during separation of adjacent semiconductor elements 10, thus facilitating the cutting. In a process step of filling with an encapsulating resin 96, the encapsulating resin 96 is also applied onto the bottom surfaces of the recessed portions 83. This embodiment has advantages similar to those of the first embodiment.

### Embodiment 3

A semiconductor device according to a third embodiment differs from that of the first embodiment only in the shape of a transparent member. Thus, aspects different from those of the first embodiment are now described.

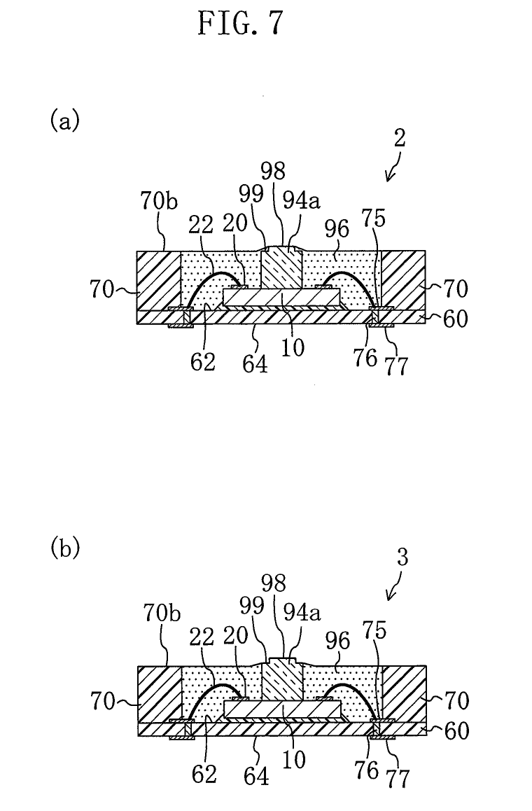

As illustrated in FIG. 7, semiconductor devices 2 and 3 according to this embodiment employ transparent members 94a which are stepped at external edges of the upper surfaces thereof. The upper surface of each of the transparent members 94a is stepped to have: a top surface 98 located in a middle portion of the upper surface and corresponding to the shape and size of the optical functional surface of a semiconductor element 10; and stepped surfaces 99 located below the top surface 98 at a distance corresponding to the steps.

In the semiconductor device 2 illustrated in FIG. 7(a), an encapsulating resin 96 covers the stepped surfaces 99, but does not cover the top surface 98. The presence of the stepped surfaces 99 in this manner ensures that the top surface 98 is not covered with the encapsulating resin 96, resulting in ensuring entering of necessary light into the optical functional surface of the semiconductor element 10, or resulting in efficient emission of light from the optical functional surface. The other advantages of this embodiment are the same as those of the first embodiment.

Alternatively, as in the semiconductor device 3 illustrated in FIG. 7(b), none of stepped surfaces 99 and a top surface 98 of a transparent member 94a may be covered with an encapsulating resin 196.

### Embodiment 4

A semiconductor device according to a fourth embodiment differs from that of the first embodiment only in a transparent member. Thus, aspects different from those of the first embodiment are now described.

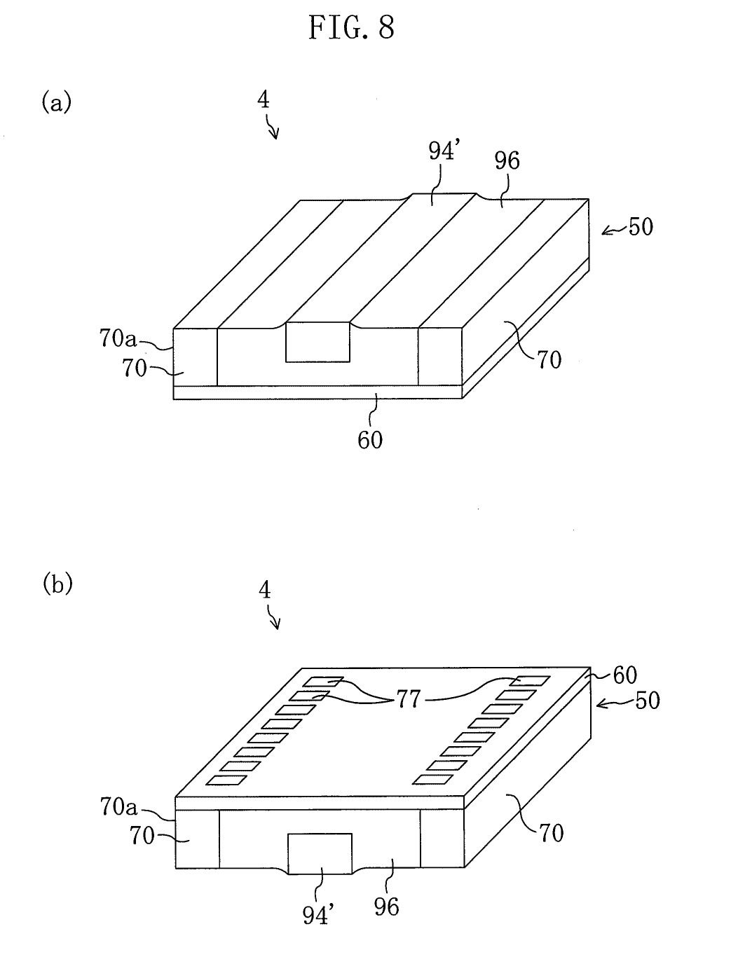

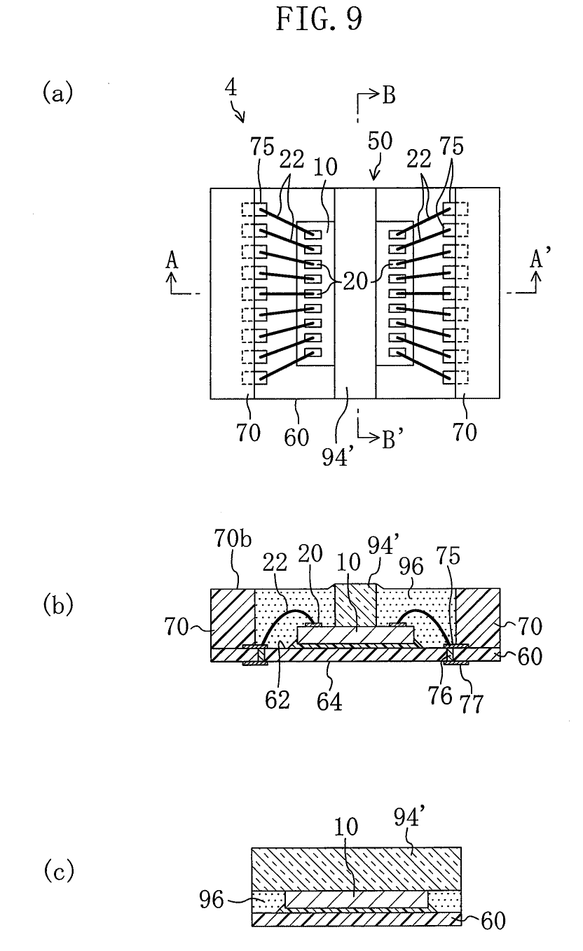

As illustrated in FIGS. 8, 9, a transparent member 94′ of a semiconductor device 4 according to this embodiment extends out from the upper surface of a semiconductor element 10, and is exposed, together with a base 60, ribs 70, 70, and an encapsulating resin 96, at a pair of side surfaces of the semiconductor device 4 perpendicular to the direction in which the ribs 70, 70 extend.

In the fabrication of the semiconductor device 1 of the first embodiment, the transparent members 94 are respectively bonded to the upper surfaces of the semiconductor elements 10. On the other hand, in this embodiment, a single long transparent member 94′ is placed on the upper surfaces of a plurality of semiconductor elements 10. Specifically, between a process step shown in FIG. 3(b) and a process step shown in FIG. 3(c), a transparent member 94′ having a substantially the same length as that of trenches 55 is prepared, and is placed on a plurality of semiconductor elements 10, 10, . . . fixed to the bottom surface of each of the trenches 55. The cross-sectional view thereof is the same as that in FIG. 3 for the first embodiment. Lastly, in separation into individual semiconductor devices, the transparent member 94′ is cut together with the base 60, the ribs 70, 70, and the encapsulating resin 96, and is exposed at the cutting plane.

In this embodiment, in addition to the advantages of the first embodiment, the process step of placing the transparent member 94′ on the semiconductor elements 10 is simplified, thus facilitating fabrication.

### Embodiment 5

A semiconductor device according to a fifth embodiment differs from that of the first embodiment only in that a recess of a package 50 is not filled with an encapsulating resin. Thus, aspects different from those of the first embodiment are now described.

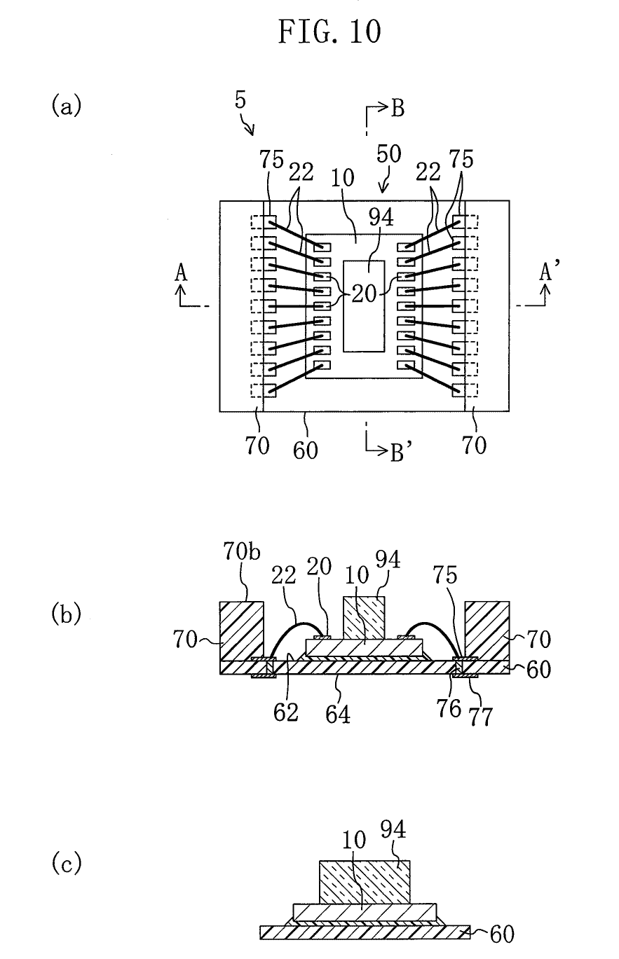

As illustrated in FIG. 10, in a semiconductor device 5 according to this embodiment, a semiconductor element 10 is not encapsulated. That is, the semiconductor device 5 of this embodiment is obtained by removing the encapsulating resin 96 from the semiconductor device 1 of the first embodiment.

The semiconductor device 5 of this embodiment is fabricated with a fabrication method in which the process performed from the state shown in FIG. 3(d) to the state shown in FIG. 3(e) is omitted in the fabrication of the semiconductor device 1 of the first embodiment.

The semiconductor device 5 of this embodiment is allowed to be fabricated with a smaller number of process steps at a lower cost, than the semiconductor device 1 of the first embodiment. In the semiconductor device 5, the light-receiving surface of the semiconductor element 10 is protected by a transparent member 94. Thus, although no foreign substances such as dust accumulate on the light-receiving surface, foreign substances such as dust might accumulate on electrode pads 20, connection electrodes 75, and metal wires 22. In this aspect, the semiconductor device 5 of this embodiment is inferior to that of the first embodiment, but in the other aspects, the same advantages as those of the first embodiment can be achieved.

### Embodiment 6

A semiconductor device according to a sixth embodiment differs from that of the first embodiment only in a package-assembled board. Thus, aspects different from those of the first embodiment are now described.

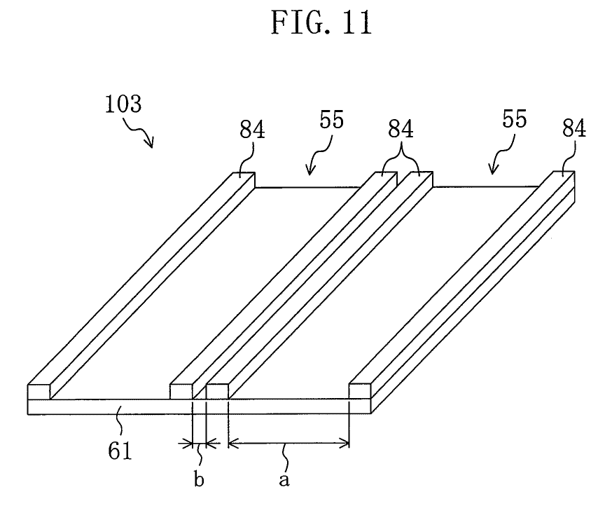

As illustrated in FIG. 11, rib prototypes 84, 84 are spaced apart at two distances, i.e., a first distance a which is relatively large and a second distance b which is smaller than the first distance a. A semiconductor element 10 is placed between each adjacent two of the rib prototypes 84, 84 separated apart at the first distance a. On the other hand, after the placement of the semiconductor element 10, each adjacent two of the rib prototypes 84, 84 separated apart at the second distance b are separated from each other with a dicing saw 40. The second distance b is preferably larger than the width of the dicing saw 40 because of the following reasons. First, the cutting with the dicing saw 40 is performed only on the base plate 61, thus facilitating the separation. In addition, the cutting causes smaller stress to be applied on a package-assembled board 103. Further, the surface roughness of rib external side wall surfaces becomes equal to that of side wall surfaces of the rib prototypes 84, thus ensuring reduction of the surface roughness of portions of an encapsulating resin 96 exposed at side wall surfaces.

This embodiment has the same advantages as those of the first embodiment. Recessed portions similar to those illustrated in FIG. 4 or 6 may be formed in the rib prototypes 84.

### Embodiment 7

A semiconductor device according to a seventh embodiment differs from that of the first embodiment only in ribs. Thus, aspects different from those of the first embodiment are now described.

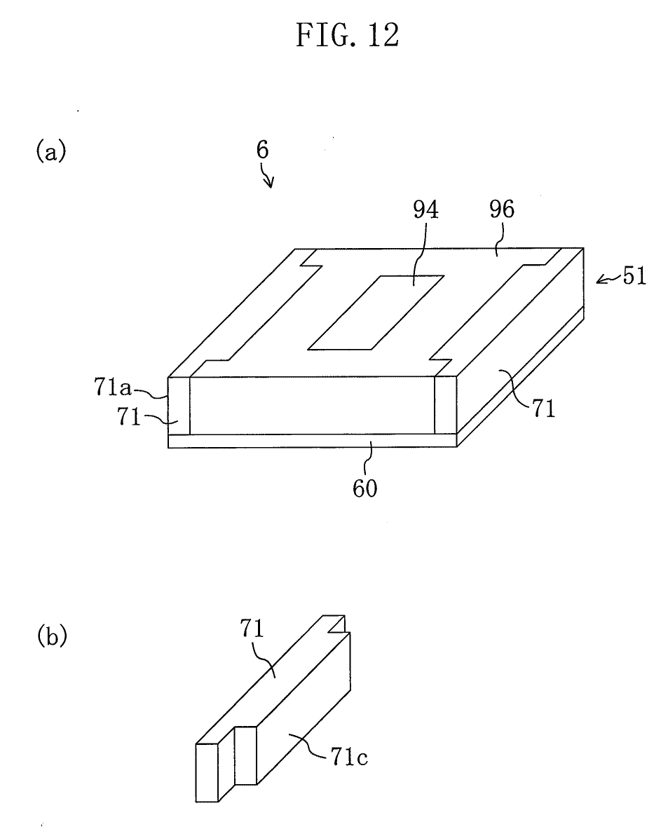

As illustrated in FIG. 12, a semiconductor device 6 according to this embodiment employs a package 51 including ribs 71 with wide portions 71c. The wide portions 71c are portions which are wide in the direction perpendicularly to the direction in which the ribs 71 extend, and project toward a center portion of a mounting surface 62. Here, the width is a distance between a rib external side wall surface 71a and a rib inner side wall surface opposite the rib external side wall surface 71a. That is, each of the ribs 71 has a structure in which end portions, in the longitudinal direction, of the rib 71 are narrow and a middle portion of the rib 71 is wide. This structure allows the ribs 71 and the encapsulating resin 96 to be bonded together in two directions (i.e., the direction parallel to the rib external side wall surfaces 71a and the direction perpendicular to the rib external side wall surfaces 71a), and increases the bonding area, thus more firmly fixing the ribs 71 to a base 60. In addition, the rib external side wall surfaces 71a and the inner wall surfaces of the ribs 71 are perpendicular to a mounting surface 62, and thus the width of the ribs 71 and the distance between the two ribs 71, 71 can be more arbitrarily selected.

The method for fabricating the semiconductor device 6 of this embodiment is substantially the same as that of the first embodiment. The difference between this embodiment and the first embodiment is only the shape of rib prototypes. For example, the semiconductor device 6 of this embodiment may be obtained by employing rib prototypes formed by increasing the length of the recessed portions 81 in the longitudinal direction of the rib prototypes 80 shown in FIG. 4. Alternatively, the semiconductor device 6 of this embodiment may be obtained by using a dicing saw with a narrow blade width in order to partially leave the recessed portions 81 in the semiconductor device in separating adjacent semiconductor elements 10, 10 along cutting lines 82.

In the same manner as that of the first embodiment, an optical pickup module can be configured by using the semiconductor device 6 of this embodiment. The semiconductor device 6, the method for fabricating the semiconductor device 6, and the optical pickup module in this embodiment have advantages similar to those of the first embodiment.

### Embodiment 8

A semiconductor device according to an eighth embodiment differs from that of the seventh embodiment only in ribs. Thus, aspects different from those of the seventh embodiment are now described.

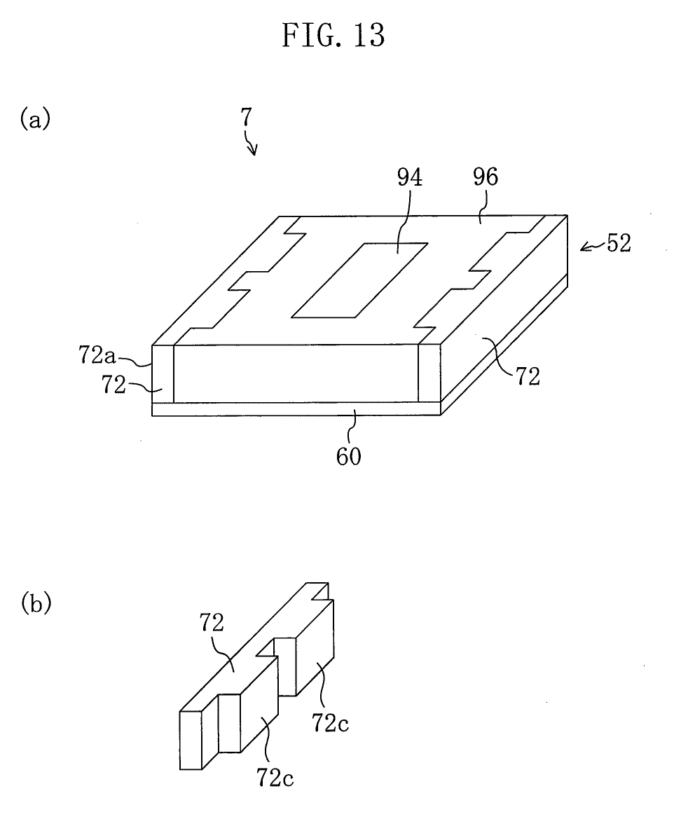

As illustrated in FIG. 13, in a semiconductor device 7 according to this embodiment, one rib 72 has two wide portions 72c, 72c. In this package 52, the rib 72 is in contact with an encapsulating resin 96 in a larger area than in the package 51 of the seventh embodiment, thus more firmly fixing the rib 72 to a base 60. The other aspects are the same as those of the seventh embodiment. Rib external side wall surfaces 72a and inner side surfaces of the ribs 72 are perpendicular to a mounting surface 62.

An optical pickup module employing the semiconductor device 7 of this embodiment has advantages similar to those of the first embodiment.

### Embodiment 9

A semiconductor device according to a ninth embodiment differs from that of the seventh embodiment only in ribs. Thus, aspects different from those of the seventh embodiment are now described.

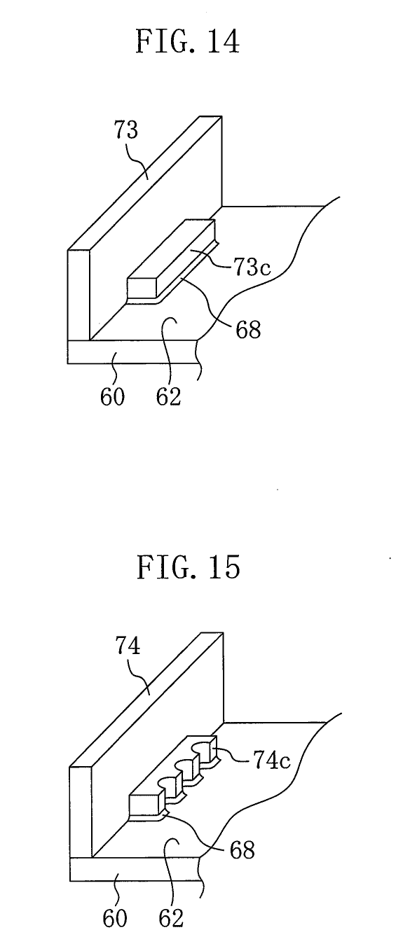

As illustrated in FIG. 14, in a rib 73 used in a semiconductor device according to this embodiment, a wide portion 73c is provided only at a lower portion of the rib 73. Specifically, the rib 73 of this embodiment has a shape obtained by dividing the wide portion 71c of the rib 71 of the seventh embodiment into upper and lower portions, and removing the upper portion with the lower portion left. Such a shape of the wide portion 73c causes an encapsulating resin 96 to push the wide portion 73c to a base 60 in this embodiment, thus more firmly fixing the rib 73 to the base 60. In addition, the lower surface of the rib 73 is fixed to the base 60 with an adhesive, and the adhesive extends out from the lower surface of the wide portion 73c to form a fillet 68 at a portion in which side wall surfaces of the wide portion 73c and a mounting surface 62 are bonded together (i.e., at a boundary at which the side wall surfaces are in contact with the mounting surface 62). This structure more firmly fixes the rib 73 to the base 60. The other advantages are the same as those of the seventh embodiment.

The shape of the wide portion may be arbitrarily selected. For example, as in a modified example illustrated in FIG. 15, a wide portion 74c of a rib 74 of this modified example has a shape obtained by cutting away three semi-cylindrical portions from the projecting end of the wide portion 73c. The rib 74 of this modified example can be more firmly fixed to a base 60 than the rib 73. For the rib 74, a fillet 68 made of an adhesive is also formed at the bonding portion between the wide portion 74c and a mounting surface 62, thus more firmly fixing the rib 74 to the base 60.

An optical pickup module employing the semiconductor device of this embodiment has advantages similar to those of the first embodiment.

### Other Embodiments

The foregoing embodiments are merely examples of the present invention, and do not limit the present invention.

The external-connection portions may be provided on an area except for the non-mounting surface of the board. For example, the external-connection portions may be provided on the rib external side wall surfaces, or may be continuously provided from the non-mounting surface to the rib external side wall surfaces. The external-connection portions and the connection electrodes do not need to be connected by internal interconnections provided in the ribs, and may be connected by wires provided along the side wall surfaces of the ribs.

The semiconductor element does not need to be a solid-state image sensor, and may be a photoreceiver such as a photocoupler or a light-emitting element such as an LED and a laser device. Further, the semiconductor element does not need to be an optical device, and may be a SAW device, an oscillator, a pressure sensor, an acceleration sensor, or a sound sensor, for example. In this case, the lid does not need to be transparent. Furthermore, the semiconductor element may be fabricated by MEMS.

Features of the foregoing embodiments may be combined. For example, in the second through fifth embodiments, the package-assembled board 103 of the sixth embodiment may be employed.

The wide portions of the seventh and eighth embodiments may have a shape as that in the modified example of the ninth embodiment. The shapes of the wide portions of the seventh through ninth embodiments are not specifically limited.

### INDUSTRIAL APPLICABILITY

As described above, a method for fabricating a semiconductor device according to the present invention is useful as a method for efficiently fabricating a small-size semiconductor device and for fabricating, for example, a photodetector for use in an optical pickup module.

1. A method for fabricating a semiconductor device including a semiconductor element and a package on which the semiconductor element is mounted, the method comprising:
providing, on an upper surface of a flat base plate, a plurality of parallel ribs projecting from the upper surface of the base plate, thereby forming a package-assembled board in which a plurality of packages are connected to one another;
placing a plurality of semiconductor elements between adjacent two of the ribs along a direction in which the ribs extend; and
cutting the package-assembled board at a middle portion of each of the ribs along the direction in which the ribs extend.

2. The method of claim 1, wherein a slit is formed in each of the ribs from an upper surface of the rib toward the base plate, and extends along a direction in which the rib extends.

3. A method for fabricating a semiconductor device including a semiconductor element and a package on which the semiconductor element is mounted, the method comprising:
providing, on an upper surface of a flat base plate, a plurality of parallel ribs projecting from the upper surface of the base plate in such a manner that the ribs are spaced apart at two distances which are alternately a first distance a and a second distance b smaller than the first distance a, thereby forming a package-assembled board in which a plurality of packages are connected to one another;
placing, along a direction in which the ribs extend, a plurality of semiconductor elements between adjacent two of the ribs spaced apart at the first distance a; and
cutting, along the direction in which the ribs extend, the package-assembled board at a portion between adjacent two of the ribs spaced apart at the second distance b.

4. The method of claim 1, wherein each of the ribs has a plurality of recessed portions, one of whose width and height is smaller than the other portion and which are arranged along the direction in which the rib extends, and
in the placing, each of the semiconductor elements is placed between adjacent two of the ribs and, in the direction in which the ribs extend, between adjacent two of the recessed portions.

5. The method of claim 1, wherein the package-assembled board includes a plurality of connection electrodes arranged on the upper surface of the base plate along the ribs, and
in the placing, the semiconductor elements and the connection electrodes are connected to each other by metal wires.

6. The method of claim 5, further comprising:
placing a transparent member having a plate shape on each of the semiconductor elements; and
encapsulating the metal wires and a side wall surface of the transparent member with an encapsulating resin.

7. The method of claim 6, wherein in the placing the transparent member, the transparent member is commonly placed on the plurality of semiconductor elements.

8. An optical pickup module, comprising:
a semiconductor device fabricated with the method of claim 1;
a laser module; and
a beam splitter, wherein
a semiconductor element included in the semiconductor device is a photoreceiver.

9. The optical pickup module of claim 8, further comprising a mirror and an objective lens.

10. The optical pickup module of claim 8, wherein the optical pickup module is placed under an information-recording surface of an optical disk, and
a direction along which the ribs extend is substantially perpendicular to the information-recording surface.

11. The optical pickup module of claim 8, wherein the laser module includes:
a blue-violet laser device configured to emit light having a peak wavelength ranging from 385 nm to 425 nm, both inclusive; and
a dual-wavelength laser device configured to emit light having a peak wavelength ranging from 630 nm to 670 nm, both inclusive, and light having a peak wavelength ranging from 760 nm to 800 nm, both inclusive.

12. A semiconductor device, comprising:
a semiconductor element; and
a package on which the semiconductor element is mounted, wherein
the semiconductor device is a substantially rectangular solid,
a bottom surface and a pair of opposite side surfaces of the semiconductor device are part of the package,
the package includes
a base which is substantially rectangular and has a mounting surface on which the semiconductor element is mounted, and
ribs respectively provided on a pair of opposite external edges of the mounting surface and extending along the pair of opposite external edges,
the semiconductor element is encapsulated with an encapsulating resin,
a pair of opposing surfaces of the respective ribs are covered with the encapsulating resin,
the board, the ribs, and the encapsulating resin are exposed at another pair of opposite side surfaces of the semiconductor device, and
a portion of each of the ribs covered with the encapsulating resin has a wide portion located at a lower surface of the rib and having a width, in a direction perpendicular to a direction in which the rib extends, larger than that of a portion of the rib exposed at one of the another pair of opposite side surfaces of the semiconductor device.

13. The semiconductor device of claim 12, wherein the lower surface of each of the ribs and the mounting surface are bonded together with an adhesive, and
the adhesive forms a fillet at a portion where a side wall surface of the wide portion and the mounting surface are bonded together.

14. The semiconductor device of claim 12, wherein a side surface of each of the ribs opposite one of opposing surfaces of the respective ribs exhibits a surface roughness smaller than that of a surface of the encapsulating resin exposed at one of the another pair of opposite side surfaces of the semiconductor device.

15. The semiconductor device of claim 12, wherein side surfaces of the ribs are substantially perpendicular to the mounting surface.

16. An optical pickup module, comprising:
the semiconductor device recited in claim 12;
a laser module; and
a beam splitter, wherein
the semiconductor element included in the semiconductor device is a photoreceiver.

17. The optical pickup module of claim 16, further comprising a mirror and an objective lens.

18. The optical pickup module of claim 16, wherein the optical pickup module is placed under an information-recording surface of an optical disk, and
a direction along which the ribs extend is substantially perpendicular to the information-recording surface.

19. The optical pickup module of claim 16, wherein
the laser module includes:
a blue-violet laser device configured to emit light having a peak wavelength ranging from 385 nm to 425 nm, both inclusive; and
a dual-wavelength laser device configured to emit light having a peak wavelength ranging from 630 nm to 670 nm, both inclusive, and light having a peak wavelength ranging from 760 nm to 800 nm, both inclusive.

20. The method of claim 3, wherein each of the ribs has a plurality of recessed portions, one of whose width and height is smaller than the other portion and which are arranged along the direction in which the rib extends, and
in the placing, each of the semiconductor elements is placed between adjacent two of the ribs and, in the direction in which the ribs extend, between adjacent two of the recessed portions.

21. The method of claim 3, wherein the package-assembled board includes a plurality of connection electrodes arranged on the upper surface of the base plate along the ribs, and
in the placing, the semiconductor elements and the connection electrodes are connected to each other by metal wires.

22. An optical pickup module, comprising:
a semiconductor device fabricated with the method of claim 3;
a laser module; and
a beam splitter, wherein
a semiconductor element included in the semiconductor device is a photoreceiver.
